(19) United States
(12) Patent Application Publication
(10) Pub. No.: US 2011/0240119 A1
(43) Pub. Date: Oct. 6, 2011

(54) METHOD FOR PREPARING SOLAR CELL ELECTRODES, SOLAR CELL SUBSTRATES PREPARED THEREBY, AND SOLAR CELLS

(76) Inventors: Su Jin Lee, Incheon (KR); Sun Chan Park, Gyeonggi-do (KR); Yong Ki Lee, Seoul (KR); Hyun Min Jung, Gyeonggi-dong (KR)

(21) Appl. No.: 13/157,422

(22) Filed: Jun. 10, 2011

Related U.S. Application Data
(63) Continuation of application No. PCT/KR2009/007390, filed on Dec. 10, 2009.

(30) Foreign Application Priority Data
Dec. 10, 2008 (KR) 10-2008-0125297

(51) Int. Cl. H01L 31/0224; H01L 31/18

(52) U.S. Cl. 136/256; 438/98; 257/E31.124

(57) ABSTRACT

The following description provides a method for preparing electrodes for solar cells, substrates for the solar cell prepared using the same, and the solar cells. The method forms conductive paste on substrates by a printing method and a wet metal plating method, and forms a non-porous cell structure by directly plating a crystallized metal layer on the substrates via etching without using excessive non-crystallized conductive paste or plating the porous conductive paste with metal.

### CROSS REFERENCE TO RELATED APPLICATION(S)

This application is a continuation of International Patent Application No. PCT/KR2009007390, filed on Dec. 10, 2009, which claims the benefit of Korean Patent Application No. 10-2008-0125297 filed on Dec. 10, 2008, the entire disclosures of which are incorporated herein by reference for all purposes.

### BACKGROUND

1. Field

The following description relates to a method for manufacturing electrodes for a solar cell, and a substrate and a solar cell manufactured using the same.

2. Description of Related Art

A solar cell is a semiconductor device for converting a solar energy to an electric energy. The solar cell has a p-n junction, and the fundamental structure thereof is the same as a diode. When a light is incident into the solar cell, the incident light is absorbed to the solar cell and is interacted with a material constituting the semiconductor of the solar cell. As a result, electrons and holes as minority carriers are formed, and they move to connected electrodes of both sides, thereby obtaining electromotive force.

Generally, crystalline silicon solar cells may be classified into a single crystal type and a polycrystalline type. A material of the single crystal type has a high efficiency due to a high purity and a low defect density, but the material of the single crystal type is expensive. Although a material of the polycrystalline type has a slightly low efficiency compared with the material of the single crystal, but it is generally used because it is relatively cheap.

A method for manufacturing the polycrystalline silicon solar cell is as follows. The p type polycrystalline silicon substrate with a certain size (for example, 5″ or 6″) and a thickness (for example, 150 to 250 μm) is etched by a proper etching method in order to eliminate defects of a surface of the substrate and to provide roughness.

Next, a material including phosphorus or POCl3 is supplied in a gaseous phase or a liquid phase, and the phosphorus is doped with a certain thickness (0.1 to 0.5 μm) of the surface of the p type substrate by a thermal diffusion. Then, an n type of emitter of 40 to 106Q/sq is formed.

After that, to remove the by-product such as vitreous material including phosphorus generated during the process, a wet etching process using an acid or a base is included. Also, in order to eliminate the phosphorous at the rest portion except for the front portion where the light is incident, a dry etching using plasma is included.

Selectively, in some cases, a process for cutting an edge surface using a laser may be included. After that, the crystalline or amorphous silicon nitride, silicon oxide, titanium oxide, or the combination thereof is deposited by a physical vapor deposition with a proper thickness (70 to 90 in the case of the silicon nitride) considering a refractive index of the deposited material. Then, an electrode of the P type semiconductor and an electrode of the N type are formed.

### SUMMARY

Related to the formation of the electrodes, the following description consider that an electrode pattern is formed by using a photo resist on a surface of a semiconductor wafer and then a metal deposition layer is formed by a deposition process. However, in the method using the photo resist, the metal deposition layer except for a portion constituting an underlayer electrode should be removed after the deposition process, and the photo resist layer should be also removed. Further, since the underlayer electrode layer is formed by the deposition method, the adhesion with the semiconductor wafer is weak.

The following description is to solve the above problem, and is to provide a method for manufacturing electrodes for a solar cell, a substrate and a solar cell manufactured by using the same. In the following description, an electrode pattern of a fine width is stacked by a printing method on a substrate for a solar cell, a crystallized layer is formed between the substrate and the stacked conductive paste layer by firing the electrode pattern, a the metallic plated layer is formed on the crystallized layer portion, and they are heat-treated. Then, an electrode structure of a non-porous plated metal is directly formed on the crystallized layer. Thus, the adhesion with the substrate can be high, and the specific resistivity of the electrode can be low.

Also, the method may have additional objects as follow. The method saves the amount of the conductive paste because the conductive paste used during stacking an electrode pattern can be formed with a minimum thickness only for forming the crystallized layer.

Also, pattern aligning problems at a manufacturing process using an offset method can be solved. For example, in the offset method (or the gravure offset method), which may be useful for forming a fine electrode pattern, the electrode patterns are generally stacked by several-times printing for achieving a suitable aspect ratio of the electrodes and reducing a line resistance. However, since the present method needs the minimum thickness only for forming the crystallized layer, a number of printing can be effectively reduced. Thus, one-time printing can be possible.

At stacking by several-times printing, the precise pattern alignment may be required. In the method where the precise pattern alignment is necessary, there are a lot of problems, for example, production may be very low and product yield may decrease. The present method has an advantage for solving several problems of the pattern alignment because a precise pattern can be obtained by one-time offset printing.

Further, since the conductive paste is printed with the minimum thickness, a low-temperature sintering or a high-temperature sintering in a very short time can be possible, compared with a relatively thick electrode pattern.

In addition, a whole portion or a part of a non-crystallized layer is removed, and thus, an overall thickness of the electrode can be thin. Accordingly, the loss caused by light shielding of the electrode can be reduced.

In order to achieve the above objects, the following description provides a substrate for a solar cell including a plurality of bus bar electrodes and finger electrodes formed on a front surface of the substrate. The bus bar electrodes and the finger electrodes are formed by forming a crystallized metal layer on the substrate and forming a plated electrode layer on the crystallized metal layer.

The conventional constitutions of the substrate for the solar cell can be applied and be added to the following description where possible. For example, the bus bar electrodes and the finger electrodes may be perpendicularly crossed with and be adjacent to each other. A rear electrode may be included on a rear surface of the substrate. Also, a kind of the substrate is not limited, and the substrate includes all substrates that can be used for the solar cell.

In the substrate for the solar cell, the crystallized metal layer is formed by printing a conductive paste and removing a whole portion or a part of a non-crystallized portion. The kind of the methods for printing the conductive paste is not limited, and includes all methods that can print the conductive paste.

Also, the firing condition after the printing is not limited. For example, the firing may fire the conductive paste at a temperature of 500 to 900° C. for several seconds to several hours. In addition, the non-crystallized portion may be removed by an etching method through using an acid solution. The substrate where the crystallized layer is formed is dipped into an acid solution, the non-crystallized portion at an upper portion of the printing electrode pattern is removed by an etching, and the plating is performed. That is, the plated electrode layer is directly formed on the crystallized layer.

The acid solution for removing the non-crystallized portion is not limited, and includes all kinds of acid solutions that can remove the conductive metal particles and the frit at the non-crystallized portion. Also, in the method for forming the plated electrode layer on the crystallized layer after removing the non-crystallized layer, the electroless plating method or the electro plating method may be used. It is preferable that the plated layer is heat-treated.

In an embodiment of the substrate for the solar cell, at least one of the bus bar electrodes and the finger electrodes has an electric property that can satisfying the specific resistivity of 3.0×10⁻⁶Ω·cm or less when a line width is 80 μm or less and a thickness is 10 μm or less.

The manufactured electrode may have an electrode structure that has no pores.

The following description also provides a solar cell manufactured by using the substrate for the solar cell.

Further, the following description provides a method for manufacturing electrodes for a solar cell that forms bus bar electrodes and finger electrodes on a substrate. The method includes forming a crystallized metal layer on a substrate by printing a conductive paste with an electrode pattern and firing the same; forming a plating seed layer by removing a whole portion or a part of a non-crystallized layer positioned on an upper portion of the crystallized layer through etching; and forming a metallic plated layer on the crystallized metal layer by dipping the substrate into a wet plating solution, after the forming the plating seed layer.

Also, the following description provides the method for manufacturing the electrodes for the solar cell where the conductive paste with an electrode pattern is printed on the substrate by only one-time offset printing.

In addition, the following description provides the method for manufacturing the electrodes for the solar cell further including heat-treating the metallic plated layer after forming the metallic plated layer.

### BRIEF DESCRIPTION OF DRAWINGS

FIG. 1 is a diagram illustrating an example of schematic cross-sectional views of a substrate for a solar cell including a plurality of bus bar electrodes and finger electrodes connected to the bus bar electrodes formed on a front surface of the substrate.

FIG. 2 is a diagram illustrating an example of a SEM (scanning electron microscope) photographs of a cross section of finger electrodes manufactured by Embodiment 1, and Comparative Examples 1 to 3.

FIG. 3 is a diagram illustrating an example of a SEM photograph of a cross section of finger electrodes where the plated electrode layer was formed on the printing electrode layer, manufactured by Embodiment 1.

FIG. 4 is a diagram illustrating an example of a graph regarding specific resistivity of the finger electrodes manufactured by Embodiment 1, and Comparative Examples 1 to 3.

### DESCRIPTION

The following detailed description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

In the method for manufacturing electrodes for a solar cell, a conductive paste is forms on a substrate by a printing method and a wet metal plating method, the unnecessarily non-crystallized portion of the conductive paste is etched and removed, and the metal is directly plated on the crystallized metal layer formed on the substrate. That is, the metal is not plated on a porous stacked conductive paste. Accordingly, the electrode structure has no pore. In addition, the adhesion between the substrate and the electrodes can be improved, and the specific resistivity of the electrodes can be reduced. For example, the cell efficiency of the solar cell can be improved by forming an additional ohmic contact among the plated metal, the crystallized metal layer as the underlayer, and the substrate via a heat-treatment process after the plating.

Also, in the method for manufacturing the electrodes for the solar cell, the amount of expensive conductive paste can be saved because the conductive paste used during stacking an electrode pattern can be formed with a minimum thickness only for forming the crystallized layer.

Further, pattern aligning problems (decreases of production and yield) at the manufacturing process can be solved because precise patterns can be obtained through one-time offset (or gravure) printing.

In addition, since the conductive paste is printed with the minimum thickness, a low-temperature sintering or a high-temperature sintering in a very short time can be possible, compared with a relatively thick electrode pattern.

Also, a whole portion or a part of a non-crystallized layer is removed, and thus, an overall thickness of the electrode can be thin. Accordingly, the loss caused by light shielding of the electrode can be reduced.

Hereinafter, with reference to drawings and embodiments, the following description is further described. The below descriptions relate to examples. Thus, even though there are conclusive and/or limitative terms or expressions, they do not limit the scope of the following description that is determined by claims.

In various aspects there is provided a substrate for a solar cell including a plurality of bus bar electrodes and finger electrodes formed on a front surface of the substrate. Here, the bus bar electrodes and the finger electrodes are formed by forming a crystallized metal layer on the substrate and then forming a plated electrode layer on the crystallized metal layer.

The electrodes formed on the substrate may be manufactured by an example method as follows. That is, the method includes a step of forming a crystallized metal layer on a substrate by printing a conductive paste with an electrode pattern and firing the same, a step of forming a plating seed layer by removing a whole portion or a part of a non-crystallized layer positioned on an upper portion of the crystallized layer through etching, and a step of forming the metallic plated layer on the crystallized metal layer by dipping the substrate into a wet plating solution after the forming the plating seed layer.

**Descriptions Regarding Main Reference Signs in Drawings**

1: substrate

2: paste electrode

21: crystallized metal layer

22: non-crystallized metal layer

3: plated layer

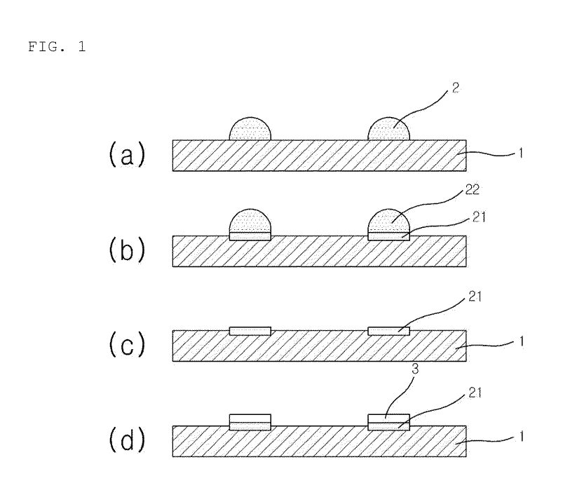

FIG. 1 illustrates an example of schematic cross-sectional views of a substrate for a solar cell. As shown, the method includes a process (a) of printing a conductive paste 2 on a substrate 1, a process (b) of forming the crystallized metal layer 21 through firing the conductive paste 2, a process (c) of forming a plating seed layer only consisting of the crystallized metal layer, and a process (d) of forming a metallic plated layer 3 on the crystallized metal layer. In the process (c), a whole portion or a part of a non-crystallized portion 22 positioned on the crystallized metal layer is etched and removed by dipping the substrate into an acid solution, and thus, the plating seed layer only consisting of the crystallized metal layer is formed for directly plating the metal on the crystallized metal layer. In the process (d), the substrate where the crystallized metal layer is formed is dipped into a wet metal plating solution, and the metallic plated layer 3 is formed only on a portion of the crystallized metal layer through directly plating the metal. Thus, an electrode layer having no pore is formed.

The metal is not plated on a stacked conductive paste that is porous. Instead, in the present invention, by etching and removing the non-crystallized portion of the conductive paste that is not necessary, the metal is directly plated on the crystallized metal layer on the substrate, thereby forming the electrode structure having no pore. In addition, the adhesion between the substrate and the electrodes can be improved, and the specific resistivity of the electrodes can be reduced. Particularly, the cell efficiency of the solar cell can be improved by forming an additional ohmic contact among the plated, and the crystallized metal layer as the underlayer, and the substrate via heat treatment after the plating. Also, since the plated layer is formed after removing the non-crystallized portion, the thickness of the electrode can be largely decreases and the light shielding ratio can be reduced. Finally, the efficiency of the solar cell can be increased.

As the conductive paste for printing the electrode, the conductive pastes having silver, copper, nickel, aluminum, and so on as a main component are generally used. Mostly, the silver paste including a silver powder may be used. The silver paste may include 60 to 80 wt % of the silver powder, 3 to 20 wt % of a glass powder, 2 to 10 wt % of a binder with a high molecule, 3 to 20 wt % of a diluting solution, and 0.1 to 5 wt % of additives.

As the printing method of the conductive paste, there are a screen printing method, an offset printing method, a gravure printing method, an inkjet printing method, and so on. The suitable printing method may be selected and used according to the pattern shape of the electrode and the properties of the used conductive paste.

In the method for manufacturing the front electrode for the solar cell, the screen printing method and the offset printing method among the above printing methods are applied. For example, in order to reduce the shading loss of the solar cell, the offset printing method with a small line width may be applied. In addition, the crystallized metal layer is formed through firing process after printing on the substrate, and the non-crystallized portion is etched and removed. Thus, the printing thickness of the electrode pattern can be at a minimum (for example, below 5 microns), the amount of the expensive conductive paste can be reduced. In addition, instead of the general offset printing where a plurality of the conductive pastes are stacked, only one-time printing can be possible if it is necessary. Accordingly, the pattern alignment is not necessary, and the production and the yield can be maximized.

Further, since the electrode pattern is printed with the minimum thickness, a low-temperature sintering or a high-temperature sintering in a very short time can be possible, compared with a relatively thick electrode pattern.

Thus, according to various examples, the conductive paste is printed through the offset method having a small line width, and is fired at a temperature of 600 to 900° C.

For example, in order to directly form the plated electrode layer on the crystallized metal layer, a part (preferably, a whole portion) of a non-crystallized portion positioned on the upper portion of the electrode pattern is etched and removed by dipping the substrate where the printing electrode pattern is formed into an acid solution. For the acid solution, a nitric acid, a hydrochloric acid, a hydrofluoric acid, an acetic acid, and so on may be suitably selected and used according to the chemical property of the conductive paste.

Generally, since the silver paste includes the silver powder and the glass frit, the non-crystallized silver paste portion may be preferably removed through dipping the substrate into the nitric acid solution or the solution including fluorine for 0.1 minute to 3 minutes. When the dipping time into the acid solution is less than 0.1 minute, the non-crystallized metal paste portion cannot be entirely removed and the plating thickness at the metal plating cannot be uniform. When the dipping time is more than 3 minutes, not only the non-crystallized metal paste portion but also the entire portion of the substrate may be chemically damaged. Thus, it is preferable that the dipping time into the acid solution is in a range from 0.1 minute to 3 minutes.

The wet metal plating may be generally classified into an electroless plating method and an electro plating method. The electroless plating method is generally used to provide conductivity to the surface, which is generally an insulator. In the electroless plating, the metal ion is reduced by using electron released through an oxidation reaction of a reducing agent in a solution where a metallic salt and a soluble reductant coexist, thereby plating the metal. Generally, in the electroless plating, the plating is performed by a selective reduction reaction of the metal ion on a catalyst surface or catalysis of the metal itself of the plated layer. The electro plating is generally used. In the electro plating, the surface of an object to be plated should be a conductive surface. The electro plating is performed by plating the metal on the conductive surface as the negative pole through using an external power.

According to various examples, since the object to be plated is the conductive portion of the crystallized metal layer, both of the electroless plating method and the electro plating method can be applied. Thus, electroless plating method, the electro plating method, or both of the electroless plating method and the electro plating method may be subjected as the wet metal plating method.

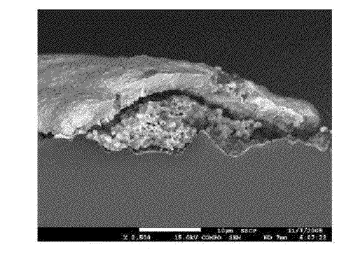

Generally, when the wet metallic plated layer is formed on the metal paste with the printed and stacked thickness more than 5 micron, the plating speed(amount) plated from the surface of the metal paste is higher (larger) than the plating speed(amount) plated into the pores. Thus, as shown in FIG. 3, the dense metal structure can be shown only at the surface of the metal paste where the ohmic contact is necessary. Also, as the thickness of the plating increases, tensile strength between the metal paste and the plated metal increases more than tensile strength between the substrate and the metal paste. Accordingly, during the plating process or after the plating process, the adhesion failure between the substrate and the metal paste may be caused.

The wet metal plating process is performed only on a portion where the crystallized metal layer is formed, not the stacked metal paste. Because the ohmic contact is formed through the firing step of the conductive paste at the portion where the crystallized metal layer is formed, the additional ohmic contact among the plated metal, the crystallized metal layer, and the substrate layer is formed through the heat-treatment process after the plating.

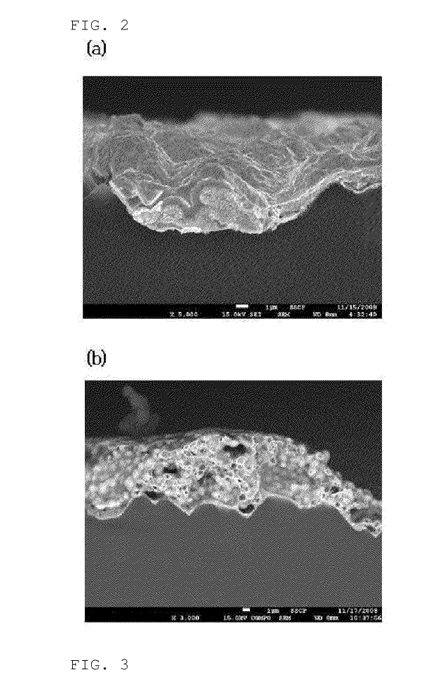

In addition, the electrode in the prior art only consisting of the conductive paste (refer to (b) of FIG. 2) has a structure having a lot of pores because an inorganic oxide such as the glass frit are remained. However, as shown in (a) of FIG. 2, the electrodes in the present invention are not the porous conductive paste layer, and include the dense metallic plated layer having no pore. Thus, the present invention can reduce the specific resistivity of the electrode.

Further, according to various examples, the metallic plated layer is directly formed on the crystallized metal layer at the wet metal plating process, and thus, the adhesion with the substrate can be improved.

A metal having a low specific resistivity may be used for the plated metal at the wet metal plating process. For example, the metal may includes at least one selected from a group consisting of silver, gold, copper, nickel, tin, and so on.

In addition, the embodiment of the present invention may include heat-treating the plated metal at a temperature of 400 to 700° C., after the wet metal plating.

### EMBODIMENT

Hereinafter, the following description will be described through example embodiments. However, the following Embodiment is only an example and the description is not limited thereto.

### Embodiment 1

Firstly, a offset printing (gravure printing) was subjected by using a paste composition for an offset (SSCP 1672 made by SSCP CO. LTD.; 68% of silver powder, 17% of glass frit, 10% of binder, 3% of diluting solvent, 2% of dispersing agent and so on). A doctoring state was check by a blade pressure and angle of an initial gravure roll, and an off pressure and a set pressure were optimized by controlling off nip and set nip of a blanket roll. After 20 g of the paste was added between the gravure roll and the blade, the doctoring was carried out with about 7 rpm. After doctoring three times or more, the paste was off to a rubber on the blanket roll, and then the blanket roll was rotated once. During the rotation of the blanket roll, the paste absorbed to the rubber was set with a velocity of 7 rpm. By the above method, the conductive paste was printed once on 5″ wafer fixed to a printing plate by vacuum. After the printed substrate was dried, the printed substrate was fired at about 800° C. for 20 seconds with a velocity of 190 rpm at an infrared furnace. Then, silicon-paste crystallized layer was formed. After that, the silicon wafer was dipped into the nitric acid solution for 1 minute in a sonicator, and the non-crystallized silver paste portion was etched and removed. Next, the silicon wafer was dipped into the solution including the fluorine for 5 seconds, and the remained and non-crystallized glass frit was removed. And then, the silicon wafer was immediately washed with diluted water and dried. Then, a portion where the electric current would be applied for electro plating of the wafer was connected to an aluminum electrode layer as a rear electrode. In the state that the whole portion of the rear electrode except for the portion where the electric current would be applied was masked in order to prevent of permeation of the plating solution, a wet metal plating was carried out. Electro silver plating was subjected as the wet metal plating process. The silver plating solution was formed with 25 g/l of silver potassium cyanide as a silver metallic salt, 75 g/l of potassium cyanide for a metallic complex salt, 30g/1 of potassium carbonate for an electrical conductivity and an uniformity of an electrodepostion, and 4 g/l of an additive of Argalux64 (made by Atotec Korea) for a density and a gloss of the plated layer. The substrate was dipped into the silver plating solution, and a silver plated layer was formed at a bath temperature of 25° C., a current density of 1.0 A/dm2, and a plating time of 10 minutes in the state that the current was applied by using a silver plate as a positive pole. Then, the plated wafer was heat-treated at a temperature of 550° C. for 10 minutes, thereby forming the electrodes for the solar cell.

### Comparative Example 1

The electrodes for the solar cell were formed by one-time printing of the paste composition for the offset and firing the same as in Embodiment without forming the additional wet plated electrode layer of Embodiment 1.

### Comparative Example 2

The electrodes for the solar cell were formed as in Comparative Example except that the paste composition for the offset was printed two times and was fired.

### Comparative Example 3

The electrodes for the solar cell were formed as in Comparative Example except that the paste composition for the offset was printed four times and was fired.

### Comparative Example 4

The paste composition for the offset was printed two times and was fired as in Comparative Example 2, and then, a metallic plated layer was formed on the printed electrode layer by a wet metal plating method as in the Embodiment.

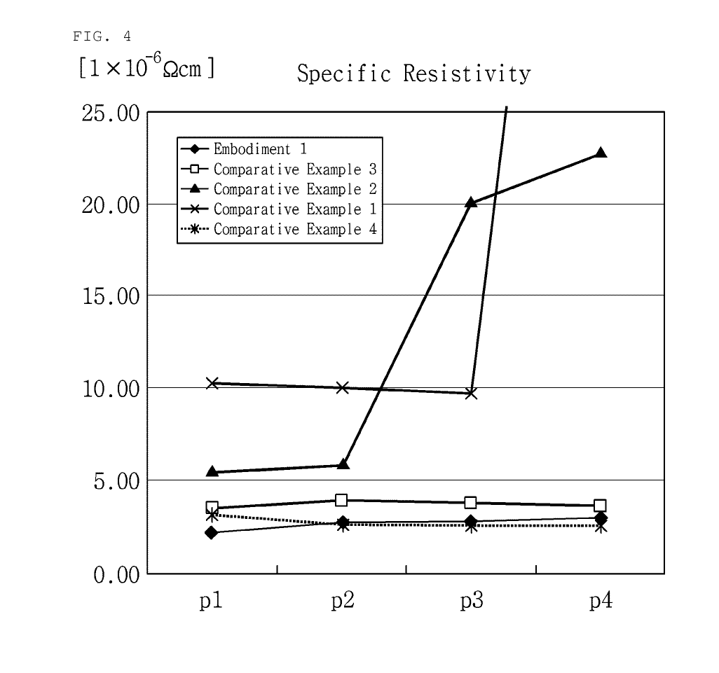

The line width, the thickness, and the line resistance of the finger electrodes for the solar cell manufacture by Embodiment and Comparative Examples were measured, and the specific resistivity of the electrode per unit length was calculated. The results are shown in Table 1 and FIG. 4.

Generally, the specific resistivity (ρ) is calculated by following Formula 1. The specific resistivity is a resistance of a unit cross section, and has a different value according to a material. The unit of the specific resistivity is Ω·m in MKS system in units, and is a reciprocal of conductivity that is a value showing how much a material allows an electric current to flows.

$$ρ = R \frac{A}{l} \qquad 〈 Formula 1 〉$$

ρ: Specific specific resistivity [Ω·m]

R: Electrical Resistance [ΩQ]

l: Length [m]

A: Cross-sectional Area [m²]

TABLE 1

| | | | Comparative | Comparative | Comparative | Comparative |
|---|---|---|---|---|---|---|
| Embodiment1 | | Embodiment1 | Example1 | Example2 | Example3 | Example4 |
| Line with of finger | | 47.29 | 40.91 | 46.31 | 30.00 | 55.71 |
| electrode [μm] | | | | | | |
| Thickness of finger | | 1.96 | 7.61 | 9.00 | 13.00 | 11.50 |
| electrode [μm] | | | | | | |
| Line Resistance | 1 cm | 2.4 | 3.3 | 1.3 | 0.9 | 0.5 |
| [Ω] | 2 cm | 5.8 | 6.4 | 2.8 | 2.0 | 0.8 |
| | 3 cm | 9.1 | 9.3 | 14.4 | 2.9 | 1.2 |
| | 4 cm | 12.9 | 84 | 21.8 | 3.7 | 1.6 |
| Specific | ρ1 | 2.23 | 10.27 | 5.42 | 3.51 | 3.2 |
| Resistivity, ρ | ρ2 | 2.69 | 9.96 | 5.84 | 3.90 | 2.56 |
| [1 × 10⁻⁶ Ω · cm] | ρ3 | 2.82 | 9.65 | 20.01 | 3.77 | 2.56 |
| | ρ4 | 2.99 | 65.38 | 22.72 | 3.61 | 2.56 |

In Comparative Examples 1 to 3, the electrodes for the solar cell consisting only of the printing electrode layer were manufactured by printing the conductive paste on the semiconductor substrate. In Embodiment 1, the electrodes for the solar cell were manufactured by forming the crystallized metal layer on the substrate and directly forming the dense plated electrode layer on the crystallized metal layer. As shown Table 1, when Embodiment is compared with Comparative Examples 1 to 3, it can be that the electrodes for the solar cell, which were manufactured by directly forming the plated electrode layer on the crystallized metal layer on the substrate, have the lower specific resistivity, although the thickness of the electrode in Embodiment is thinner than that in Examples 1 to 3. In addition, the electrodes for the solar cell in Comparative Example 4 manufactured by forming the plated electrode layer on the printing electrode layer has the specific resistivity similar to that of the electrodes for the solar cell in Embodiment. Considering the difference in electrode thickness, the thickness of the electrode can decreases in the present invention. When the electrode is thin, the loss in efficiency caused by light shielding can be reduced. Also, the electrodes manufactured by the method in Embodiment of the present invention has the specific resistivity similar to the specific resistivity of a pure silver metal (1.59×10⁻⁶Ω·cm). That is, the difference in the specific resistivity between the electrode in Embodiment and the pure silver metal is small.

Described herein is a method for preparing electrodes for solar cells, substrates for the solar cell prepared using the same, and the solar cells. The method forms conductive paste on substrates by a printing method and a wet metal plating method, and forms a non-porous cell structure by directly plating a crystallized metal layer on the substrates via etching without using excessive non-crystallized conductive paste or plating the porous conductive paste with metal.

The method described herein improves adhesion between the substrates and electrodes and reduces resistivity of the electrodes. In particular the method improves the efficiency of the solar cells by forming an additional ohmic contact among the plated metal, crystallized metal layer and substrate via heat treatment. The method saves on the amount of expensive conductive paste to be used by allowing minimum printing only to form the crystallized metal layer, solves pattern aligning problems, which decrease production and yield, by use of precise patterns through one-time offset printing, and enables high or low temperature sintering in a very short time in comparison to relatively thick electrode patterns, and reduces decreases in efficiency caused by light shielding of the electrodes.

Program instructions to perform a method described herein, or one or more operations thereof, may be recorded, stored, or fixed in one or more computer-readable storage media. The program instructions may be implemented by a computer. For example, the computer may cause a processor to execute the program instructions. The media may include, alone or in combination with the program instructions, data files, data structures, and the like. Examples of computer-readable storage media include magnetic media, such as hard disks, floppy disks, and magnetic tape; optical media such as CD ROM disks and DVDs; magneto-optical media, such as optical disks; and hardware devices that are specially configured to store and perform program instructions, such as read-only memory (ROM), random access memory (RAM), flash memory, and the like. Examples of program instructions include machine code, such as produced by a compiler, and files containing higher level code that may be executed by the computer using an interpreter. The program instructions, that is, software, may be distributed over network coupled computer systems so that the software is stored and executed in a distributed fashion. For example, the software and data may be stored by one or more computer readable storage mediums. Also, functional programs, codes, and code segments for accomplishing the example embodiments disclosed herein can be easily construed by programmers skilled in the art to which the embodiments pertain based on and using the flow diagrams and block diagrams of the figures and their corresponding descriptions as provided herein. Also, the described unit to perform an operation or a method may be hardware, software, or some combination of hardware and software. For example, the unit may be a software package running on a computer or the computer on which that software is running.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

1. A substrate for a solar cell, the substrate comprising:
a plurality of bus bar electrodes and finger electrodes formed on a front surface of the substrate,
wherein the bus bar electrodes and the finger electrodes are formed by forming a crystallized metal layer on the substrate and forming an plated electrode layer on the crystallized metal layer.

2. The substrate of claim 1, wherein the crystallized metal layer is formed by printing a conductive paste and removing a whole portion or a part of a non-crystallized portion.

3. The substrate of claim 2, wherein the non-crystallized portion is removed by an etching method through using an acid solution.

4. The substrate of claim 1, wherein the plated layer is heat-treated.

5. The substrate of claim 1, wherein at least one of the bus bar electrodes and the finger electrodes has a thickness of 10 μm or less.

6. The substrate of claim 1, wherein at least one of the bus bar electrodes and the finger electrodes has a specific resistivity of 3.0×10⁻⁶Ω·cm or less when a line width is 80 μm or less and a thickness is 10 μm or less.

7. The substrate of claim 1, wherein at least one of the bus bar electrodes and the finger electrodes has no pore.

8. A solar cell manufactured using the substrate of claim 1.

9. A method for manufacturing electrodes that includes manufacturing bus bar electrodes and finger electrodes formed on a substrate, the method comprising:
forming a crystallized metal layer on a substrate by printing a conductive paste with an electrode pattern and firing the same,
forming a plating seed layer by removing a whole portion or a part of a non-crystallized layer positioned on an upper portion of the crystallized layer through etching; and
forming a metallic plated layer on the crystallized metal layer by dipping the substrate into a wet plating solution, after the forming the plating seed layer.

10. The method of claim 9, wherein the non-crystallized layer is removed by the etching, and the substrate is dipped into an acid solution with a dipping time of 0.1 minute to 3 minutes.

11. The method of claim 9, wherein the conductive paste with the electrode pattern is printed on the substrate by a one-time offset printing.

12. The method of claim 9, further comprising:
heat-treating the metallic plated layer after forming the metallic plated layer.
